(19) United States
(12) Patent Application Publication
(10) Pub. No.: US 2002/0009900 A1
(43) Pub. Date: Jan. 24, 2002

(54) Growth of ultrathin nitride on Si (100) by rapid thermal N2 treatment

(76) Inventors: Sing Pin Tay, Fremont, CA (US); Zhenghong Lu, Toronto (CA)

Correspondence Address: Rodney T. Hodgson, Ph.D., 822 Pines Bridge Rd., Ossining, NY, 10562, US

(21) Appl. No.: 09/745,200

(22) Filed: Dec. 21, 2000

Related U.S. Application Data
(60) Provisional application No. 60/171,332, filed on Dec. 21, 1999.
(60) Provisional application No. 60/204,255, filed on May 15, 2000.

(51) Int. Cl. H01L 21/44; H01L 21/31; H01L 21/469; H01L 21/26; H01L 21/324; H01L 21/477

(52) U.S. Cl. 438/786; 438/795; 438/778; 438/782; 438/759

(57) ABSTRACT

A silicon containing wafer is heated in a rapid thermal processing (RTP) system in a nitrogen containing gas to a temperature an time where a thin oxide film on the wafer surface at least partially decomposes and a thin nitride or oxynitride film grows.

### CROSS REFERENCE TO RELATED APPLICATIONS

This application claims priority pursuant to 35 U.S.C. 119(e) to U.S. Provisional Application No. 60/171,332 filed Dec. 21, 1999 and to U.S. Provisional Application No. 60/204,255filed May 15, 2000. The above applications being incorporated herein by reference in their entirety including incorporated material.

### FIELD OF THE INVENTION

This invention is in the field of producing thin films on the surface of semiconductor wafers by rapid thermal processing (RTP), wherein process gases in the RTP chamber react with material of the semiconductor to produce the thin film.

### BACKGROUND OF THE INVENTION

Thin gate dielectric film is one of the most critical materials in enabling the deep submicron integrated circuits. Conventional thermal silicon oxide, where the semiconductor is heated in an oxygen atmosphere and the oxide “grows” by consuming the silicon on the wafer surface, has worked extremely well up to now. With continuous scaling-down in the film thickness, however, alternative gate dielectrics may have to be used to counter problems such as electron tunneling and boron diffusion, as is noted by L. C. Feldman, E. P. Gusev, and E. Garfunkel, “Ultrathin dielectrics in silicon microelectronics-an overview”, in “Fundamental Aspects of Ultrathin dielectrics on Si-based Devices”, edited by E. Garfunkel, E. Gusev, and A. Vul (Kluwer Academic, Boston, 1998).

Silicon nitride is among the most attractive candidates for replacing SiO₂ in future generations of gate dielectric.

The most common route in producing SiNₓ, SiₓN_{y} or Si_{z}OₓN_{y} dielectrics is through various forms of deposition methods (see, for example “Ultrathin SiO₂ and High-K Materials for ULSI Gate Dielectrics”, Mat. Res. Soc. Symp. Proc. Vol. 567 (MRS, Warrendale, 1999). Such deposition methods have the materials for the dielectric thin film carried in a process gas to the semiconductor surface. The process gas reacts on or near the surface to form the thin film. When the process gas reacts because the temperature is high, the process is called chemical vapor deposition (CVD). In some cases, energy is added by non thermal means such as running an electrical current through the process gas to form a plasma, and such a process is called Plasma Enhanced CVD (PECVD). The interface between the films produced in such deposition processes and the so called growth processes is different, and the deposited films of silicon nitride or mixed oxygen and nitrogen containing oxide (oxynitride) films have not exhibited characteristics superior to the grown oxide films.

Direct reaction of N₂ with silicon at relatively high temperature (>1200° C.) in ovens has been shown in the production of sintered Si₃N₄ by S. M. Hu, J. Electrochem. Soc. 113, 693 (1966), by A. Atkinson, a. J. Moulson, and E. W. Roberts, J. Am. Ceran. Soc. 59, 285 (1976), and T. Ito, S. Hijiya, T. Nozaki, H. Arakawa, M. Shinoda, and Y. Fukukawa, J. Electrochem. Soc. 125, 443 (1978). However, because of the high temperatures thought to be necessary, RTP production of Silicon Nitride alone has been neglected.

Direct nitridation of silicon followed by attempts at oxidation, has been studied by C. A. Paz, de Araujo, Y. P. Huang, R. Gallegos in J. Electrochem. Soc. 136, 2035 (1989) to show that a nitride surface inhibits oxide growth.

M. L. Green, T. Sorsch, L. C. Feldman, W. L. Lennard, E. P. Gusev, E. Garfunkel, H. C. Lu and T. Gustafsson, have shown that nitrogen may be incorporated in an oxide film at temperatures less than 1050° C. in Appl. Phys. Left. 71, 2978 (1997) and in U.S. Pat. Nos. 5,861,651 and 5,904,523. An process gas atmosphere with unknown water vapor and oxygen content was used, and no measurements were made of film quality. The incorporation of nitrogen into the film was attributed to catalytic activity of the process gas.

In U.S. patent application Ser. No. 09/212,495, filed Dec. 15, 1998, assigned to the assignee of the present application, it is shown that nitrogen may be incorporated into the thin film at temperatures under 1050° C. Electrical characteristics of the films were presented.

The prior art shows no examples of electrically excellent films of silicon nitride or silicon oxynitride which may be directly grown on the surface of silicon or silicon germanium wafers at temperatures required for thermal budgets of modem semiconductor processing.

The above identified references, applications and patents, including appendices and references, are hereby incorporated herein by reference.

### RELATED PATENTS AND APPLICATIONS

Reactors based on the RTP principle often have the entire cross section of one end of the reactor chamber open during the wafer handling process. This construction has been established because the various wafer holders, guard rings, and gas distribution plates, which have significantly greater dimensions and may be thicker than the wafers, must also be introduced into the chamber and must be easily and quickly changed when the process is changed or when different wafer sizes, for example, are used. The reaction chamber dimensions are designed with these ancillary pieces in mind. U.S. Pat. No. 5,580,830 teaches the importance of the gas flow and the use of an aperture in the door to regulate gas flow and control impurities in the process chamber.

The importance of measuring the temperature of the wafer using a pyrometer of very broad spectral response is taught in U.S. Pat. No. 5,628,564.

The wafer to be heated in a conventional RTP system typically rests on a plurality of quartz pins which hold the wafer accurately parallel to the reflector walls of the system. Prior art systems have rested the wafer on an instrumented susceptor, typically a uniform silicon wafer. U.S. Pat. No. 5,861,609 teaches the importance of susceptor plates separated from the wafer.

A method of RTP of a substrate where a small amount of a reactive gas is used to control the etching of oxides or semiconductor is disclosed in U.S. Pat. No. 6,100,149. A method of RTP of a substrate where evaporation of the silicon is controlled is disclosed in U.S. Pat. No. 6,077,751.

Methods of rotating the wafer in an RTP system are disclosed in U.S. Pat. Nos. 5,965,047 and 6,005,226.

U.S. patent application Ser. No. 09/212,495, filed Dec. 15, 1998 shows that nitrogen may be incorporated into the thin film at temperatures under 1050° C.

The above identified applications are assigned to the assignee of the present invention and are hereby incorporated herein by reference.

### OBJECTS OF THE INVENTION

It is an object of the invention to grow pure ultrathin silicon nitride films on silicon or silicon-germanium wafers by direct rapid thermal nitridation treatment.

It is an object of the invention to grow pure ultrathin silicon oxynitride films on silicon or silicon-germanium wafers by direct rapid thermal nitridation treatment.

It is an object of the invention to grow pure ultrathin silicon nitride and silicon oxide bilayer and multilayer films on silicon or silicon-germanium wafers by direct rapid thermal nitridation treatment.

### SUMMARY OF THE INVENTION

A semiconductor wafer comprising silicon is heated in an RTP chamber in a nitrogen containing process gas. The process gas contains so little oxygen containing gas or gases that a thin oxide film which either was present on the wafer at the start of the process or grows due to the presence of the oxygen containing gases may be partially or totally removed at a temperature greater than 1050° C. The nitrogen containing gas then reacts with silicon from the substrate to form a silicon nitride or a silicon oxynitride film. Further treatment in a higher pressure of oxygen containing gas may increase the film thickness or produce a bilayer film or multilayer films of silicon oxide, silcon oxynitride or silicon nitride.

The objects of the present invention are solved by a method for Rapid Thermal Processing (RTP) for producing a film on a surface of a semiconductor wafer comprising silicon. The method comprises the steps of introducing the wafer into the processing chamber of an RTP system; and then rapidly heating the semiconductor wafer to a temperature T greater than 1050° C. in an atmosphere of at least one nitrogen containing gas, wherein the atmosphere is sufficiently free of oxygen containing gases such that oxygen is at least partially removed from a first thin film on the surface of the wafer, and wherein nitrogen from the nitrogen containing gas reacts with the surface and is incorporated into the first thin film on the surface of the semiconductor wafer.

A gas is sufficiently free of oxygen containing gas if oxygen is at least partially removed from the first film of the wafer if the wafer is heated to about 1050° C. or to a higher temperature. Due to this the concentration of the oxygen containing gas depends on the gas itself. As an example, in the case that the oxygen containing gas is O₂ the concentration is typically less than 30 ppm, more preferably less than 10 ppm and most preferable less than 4 ppm. If the oxygen containing gas is H₂O the concentration is less than 10 ppm, more preferable less than 1 ppm and most preferable less than 500 ppb.

In a preferred embodiment ofthe invention no oxygen remains in the first thin film on the surface of the semiconductor wafer heating the wafer to the temperature higher than 1050° C. To prevent etch reactions on the wafer surface the concentration of the oxygen containing gases can be controlled as a function of temperature. If the oxygen containing gases are O₂ and/or H₂O the concentration can be reduced dramatically if the temperature of the wafer exceeds 1050° C., such that etching is prevented. For these gases the respective concentration is preferably below 1 ppm if the temperature of the wafer is above 1050° C. up to 1300° C. In general, the concentration of the individual gas components (the oxygen containing and/or the nitrogen containing gases) can be controlled as a function of process time and temperature such that no oxygen remains in the first film. To minimize the thermal budget of the semiconductor wafer and to make sure that no oxygen remains in the first film, the wafer is rapidly heated to a temperature greater than or equal to 1150° C. Preferably ramp rates of more than 50° C./s are used, more preferably more than 150° C./s up to 500° C./s. However, for preventing wafer damage the ramp rate itself can be controlled as a function of wafer temperature and/or the temperature gradients on the wafer, meaning the temperature gradients between the front and the backside of the wafer or across the wafer or local gradients on the wafer surface. Also the concentration of the oxygen containing gas is preferably determined or controlled by taking into account the temperature ramp rate and absolute temperature to which the wafer is heated or vice versa, the ramp rate and/or the absolute temperature to which the wafer is heated is dependent or controlled in dependence of the oxygen containing gas. The same kind of dependence or control can be used in temperature ramp down of the wafer temperature.

The just described preferred embodiment advantageously offers the possibility to generate a film consisting of pure silicon nitride (Si₃N₄) independently whether there was a native oxide on the wafer or whether the process gas is contaminated by small amounts of oxygen containing gases. Depending on the amount of the contamination of the oxygen containing gases in the process gas and/or the thickness of the native oxide or rather equivalent of an oxide layer present before the RTP process, the temperature and time for processing the wafer above 1050° C. can be determined. For commonly used RTP reactors the formation temperature for the pure silicon nitride layer is equal or higher than 1150° C., and the process time at this temperature is less than 300 seconds, depending also on the required thickness of the silicon nitride film which is in the range of about 0.3 nm and 1.6 nm.

Further, application of short wavelength ultraviolet radiation or the generation of nitrogen radicals by electrical gas discharge mechanisms additionally can support the nitridation process resulting in reduced process time.

A further advantage of the described process of forming a pure silicon nitride film is that while ramping down the wafer temperature, the silicon nitride layer can be oxidized by having a controlled amount of the oxygen containing gas in the process gas. For example such an oxidation can be done by predetermined temperature ramp down of the wafer temperature or by applying an additional oxidation step after the nitridation of the wafer. Such an additional step e.g. can be, holding the wafer at a temperature between 800° C. and 1100° C. for a time interval of less than 120 seconds, preferably less than 60 second but longer than 1 second. Also during this oxidation step the application of ultraviolet radiation can be of advantage. The described process has the advantage that a silicon nitride film or a silicon nitride film followed by an oxidation can be carried out in one process cycle without the need of changing the process chamber. Further, the process is insensitive regarding the mentioned contamination of oxygen containing gases, mainly H₂O or O₂ which are present from the atmosphere and which are usually adsorbed at the chamber walls. Also the process is rather insensitive of the thickness of an initial silicon oxide layer. For these reasons the described process generated very reliable and most advantage very reproducible silicon nitride film which optionally can also be oxidized while wafer temperature is ramped down or by an additional oxidation step after the nitridation. Most advantageous is that the described inventive process can be done in pure N₂ (apart from the mentioned small concentrations of oxygen containing gases or also contamination of oxygen containing gases). Such the described process is uncritical in gas engineering and also in cost of ownership.

Further examples of the embodiment just described is an additional sequential step used after heating the wafer equal to 1150° C. or greater. The step comprises rapidly heating the wafer in an atmosphere containing a sufficient level of an oxygen containing gas such that oxygen is incorporated in a second thin film on the surface of the semiconductor wafer. The wafer temperature is in the range of 1150° C. up to 1300° C. The oxygen containing gas preferably is selected from or is a combination of the gas O₂, H₂O, NO, N₂O, O₃. The time for this additional sequential step is preferably less than 60 s, most preferably less than 30 s, but more than 1 s. Also the application of ultraviolet radiation can be used to generate O₃ from molecular oxygen or to support the generation of molecular oxygen to improve the incorporation of oxygen into the second thin film. The application of UV radiation preferably but not necessarily is limited to the additional step, heating the wafer above 1150° C. Preferably the wafer is rapidly heated to a temperature greater than or equal to 1200° C. in the additional step.

In one embodiment of the invention the first thin film grows during the heating of the wafer to the temperature T. While growing the thin film the composition or concentration and/or composition of the oxygen and/or nitrogen containing gases can be controlled as a function of wafer temperature and/or film thickness. Also the temperature of the gases can be controlled such that the gasses are preheated to a predetermined temperature before entering the process chamber.

In an further embodiment of the invention the silicon, oxygen, and nitrogen remain in the first thin film on the surface of the semiconductor wafer after the semiconductor wafer has a temperature greater than 1050° C. Preferably the wafer is heated to a temperature greater than or equal to 1150° C.

In an further embodiment of the invention the silicon, oxygen, and nitrogen remain in the first thin film on the surface of the semiconductor wafer after the semiconductor wafer has a temperature greater than 1050° C., and an additional sequential step is applied of rapidly heating the wafer in an atmosphere containing a sufficient level of an oxygen containing gas that the first thin film is increased in thickness. The concentration and/or composition of the oxygen containing gas preferably is controllable such that it can be controlled as a function of wafer temperature and/or process time and/or film composition or thickness. To increase the first film in thickness (e.g. a SiO₂-film), preferably the concentration of the oxygen containing gas is more than 1 ppm. In the case of O₂ the concentration preferably is higher than 4 ppm, most preferably the concentration is more than 30 ppm and less than 10000 ppm.

In a further embodiment the semiconductor wafer further comprises germanium.

Preferred nitrogen containing gases are selected from N₂, NH₃, NO, N₂O or NF₃. However, also combinations of any of these gases in various compositions can be used, like e.g. a combination of N₂ and N₂O or NO and NH₃ . Also dilution in an inert gas like Ar or He can be done.

Further, a sequential step after heating the first film to the temperature T is applied by rapidly heating the wafer in an atmosphere containing a sufficient level of an oxygen containing gas that the thickness of the thin film is increased. Preferably but not necessarily restricted to, this additional step is applied if the nitrogen containing gases are selected from N₂, NH₃, or NF₃ or are combinations of these gases. Also the oxygen containing gas can be controlled such as described in the embodiments above for oxygen and nitrogen containing gases. The application of additional ultraviolet radiation also can be of advantage for certain oxygen containing gases to improve film growth rate and electrical film properties.

An other embodiment of the invention comprises a step of rapidly heating the wafer in an atmosphere containing a sufficient level of an oxygen containing gas that the thickness ofthe first thin film is increased. In this embodiment a high quality silicon oxide like a gate oxide is generated at temperatures below 1150° C. (e.g. at temperatures between 950° C. and 11 00C for about 1 to 30 seconds). Then after growing the high quality silicon oxide, wafer temperature is ramped up to 1150° C. or more, and nitridation of the silicon oxide is done for e.g. less than 60 seconds.

A further embodiment of the invention comprising a step in which the first film is produced in an oxygen containing gas after introducing the wafer into a process chamber of an RTP system and heating to temperatures less or equal than 1050° C. Preferably after generating this first thin film, the wafer is heated to a temperature T greater than 1050° C. in an atmosphere of at least one nitrogen containing gas, wherein the atmosphere is sufficiently free of oxygen containing gases such that oxygen is at least partially removed from a first thin film on the surface of the wafer, and wherein nitrogen from the nitrogen containing gas reacts with the surface and is incorporated into the first thin film on the surface of the semiconductor wafer, and wherein the wafer is processed without removing from the RTP processing chamber.

In an additional embodiment of the invention the processing chamber is purged with NH₃ gas to remove adsorbed H₂O from the chamber walls and other equipment of the RTP system. Preferably the purge is done at wafer temperatures of about 100° C. up to 500° C. for about 5 to 60 seconds. Then after the purge step, the wafer is processed according to one of the previous described embodiments. This purge step has the advantage that the contamination of water is reduced very quickly below 1 ppm such that the process time at temperatures above 1050° C. can be reduced at processes at which the first film have to be removed, since there is roughly no additional oxidation due to water contamination resulting from adsorbed water. Such the overall thermal budget can be reduced.

The invention now is described with the help of the following examples by referring to the accompanying figures. Further, the features ofthe above described embodiments of the invention as well as the features of the following examples also can be combined or interchanges both, as a whole or in part without departing from the teaching of the present invention.

### BRIEF DESCRIPTION OF THE DRAWINGS

FIG. 1 shows Si 2p core level spectra.

FIG. 2 shows N I s core level spectra as a function of N₂ exposure time at 1150° C.

FIG. 3 shows the nitride thickness as a function of N₂ exposure time at 1150° C.

FIG. 4 shows the N content of oxynitride films.

FIG. 5 shows a high frequency capacitance-voltage of various dielectric films

FIG. 6 shows a current-voltage characteristics of various dielectric films.

### DETAILED DESCRIPTION OF THE INVENTION

The nitridation was carried out in a Steag Heatpulse 410 rapid thermal processing (RTP) apparatus. Boron-doped Si (100) wafers, 100-mm in diameter, were used for the nitridation experiment. All wafers were cleaned using the RCA clean recipes and then dipped in an aqueous HF solution to remove the native surface oxide. The cleaned wafers were loaded into the RTP for nitride growth. The film thickness and chemical composition were studied by X-ray photoelectron spectroscopy (XPS). The XPS measurements were carried out in a PHI 5500 system which is equipped with a monochromatic Al K_{α} source and a hemispherical electron analyzer. As there is no accurate photoelectron mean free path value for the silicon nitride, we used parameters calibrated for the SiO₂ to obtain nitride thickness.

MOS capacitors were fabricated on 10-25 Ω-cm (100) p-type Si substrates that were cleaned using standard RCA clean. Five kinds of gate dielectrics were prepared according to the conditions listed in table 1. The polysilicon-gate, 300 nm thick, was deposited by LPCVD at 625° C. with a doping concentration of ˜1×10²⁰/cm³. After activating the impurities, Al was sputtered and the wafers were then sintered in forming gas at 435° C. for 25 min. The gates were defined by wet etching. For this study, we used square capacitors with an area of 3.36×10⁻³ cm². The instruments used to test the capacitors include an HP 4155A Semiconductor Parameter Analyser for leakage current measurements, and an HP 4280A for high-frequency (1 MHz) C-V measurements.

TABLE 1
Oxynitride growth conditions for MOS capacitors

| SAMPLE | STEP 1 | STEP 2 | Physical thickness |
|---|---|---|---|
| RNO | N₂, 1150° C., 20 s | O₂, 1050° C., 60 s | 32 Å |
| RON | O₂, 850° C., 60 s | N₂, 1200° C., 60 s | 14 Å |
| OX | O₂, 1020° C., 60 s | | 32 Å |

Results and Discussions

Growth of Ultrathin Si nitride

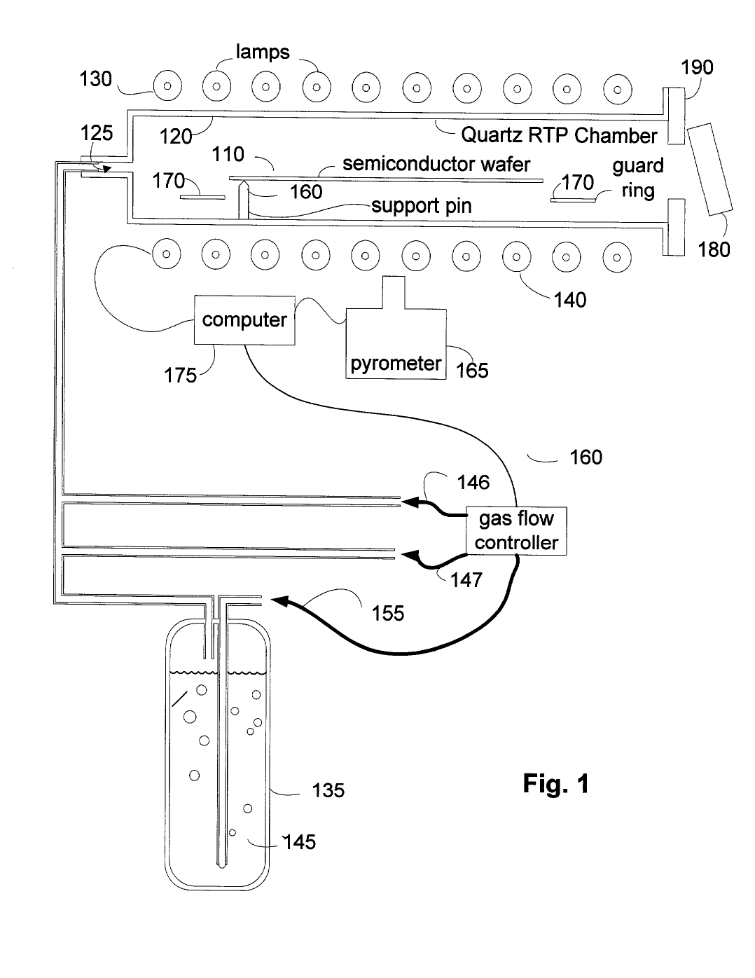

FIG. 1 shows Si 2p core level spectra recorded from the samples exposed to N₂ at 1150° C. for various times, as labeled. In our experiments, we carefully controlled water vapor to avoid rapid oxide growth during temperature ramp up. There is no indication of nitride formation at temperatures below 1150° C. With the addition of water vapor or other catalytic gases, we expect that nitrogen could be incorporated in the film at slightly lower temperatures such as 1100° C. or perhaps down to 1050° C. As can be observed from FIG. 1 there are two doublet peaks observed on surface with a short 1 s duration at 1150° C. The doublet is caused by spin-orbit splitting, p_{1/2} and p_{3/2}, which have a width energy separation of 0.6 eV and an intensity ratio 1/2. The doublet with the p_{3/2} position at about 99 eV is from the bulk silicon. Based on its binding energy, the second doublet (not resolved) at about 103 eV is attributed to SiO₂ [8]. The formation of such SiO₂ film is attributed to surface oxidation by the residual oxygen in the RTP system during temperature ramp up. For a 10 s duration, it is found that the intensity of the SiO₂ peak at about 103 eV is dramatically reduced. It is well known that SiO₂ films convert to SiO at temperatures in the range about 1150° C. The SiO is volatile at these temperatures and leaves the surface.

FIG. 1 shows that another doublet peak at about 101.2 eV emerged for 10 sec and longer durations. This latter peak with a chemical shift of 2.37 eV is characteristic of Si₃N₄ species. With a longer time N₂ treatment, the nitride peak intensity increases. This indicates growth of nitride film on the silicon surface.

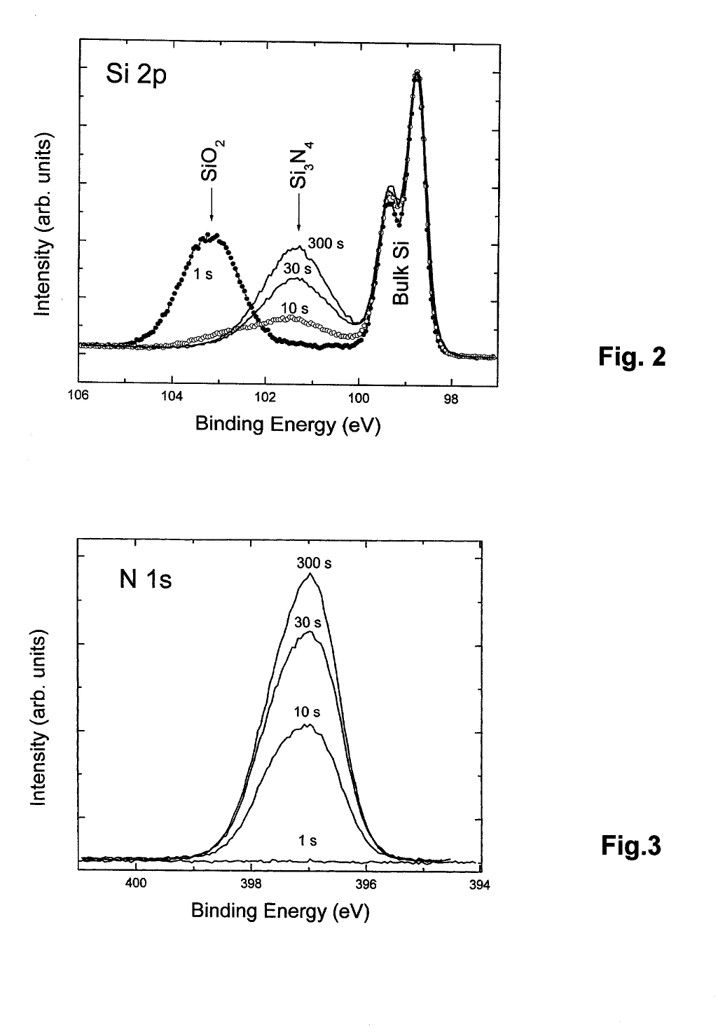

FIG. 2 shows N 1 s core level spectra as a function of N₂ exposure time at 1150° C. The intensities of the spectra were as recorded. As can be seen from the figure that there is no indication of N peak for a short 1 s exposure, confirming Si 2p data of no nitride formation.

With a longer (>1 s) duration time, a stronger N 1 s peak becomes visible and its spectral intensity increases with increasing N₂ exposure time. The oxide signal disappears. The binding energy of N 1 s peak is found to be at 397 eV, characteristic of Si₃N₄ species. This indicates that N has reacted with the silicon surface to form nitride. The nitride formation increases with increasing N₂ exposure time.

FIG. 3 shows the nitride thickness as a function of N₂ exposure time at 1150° C. The thickness is found to saturate very quickly after 60 s exposure. This growth kinetics may be explained by a logarithmic growth model. The nitride thickness (in an unit of Å), d, as a function of exposure time (in an unit of sec), t, may be fitted to an equation, d=A log (Bt+1)+C, where the constants A, B and C take values of 2.6, 30, and 5, respectively. A constant of 5 Å at t=0 sec indicates the fact that nitridation starts on an oxidized surface with an equivalent (in terms of N diffusion coefficient) of 0.5 nm nitride. The inset shows the thickness as a function of nitridation temperature at a constant 60 s exposure time. The nitride thickness is found to increase linearly as a function of temperature.

Now let us discuss possible mechanisms for the nitride formation. It is evident that there is a thin SiO₂ formed during temperature ramp up. As soon as the temperature reaches a critical temperature (≧1150° C. in our experiments), the SiO₂ film starts to decompose and the nitride starts to form. Possible reactions are the direct thermal decomposition of oxide, or perhaps a chemical reaction process, 2N₂+4Si+SiO₂→Si₃N₄+2SiO. In either case, the SiO escapes as a gas. This initial nitridation proceeds at a very fast rate until all oxide has been converted into nitride and only Si₃N₄ is left on the silicon surface. The nitride is well known for its ability to block the diffusion of impurities and reactants. Therefore a thin nitride film effectively blocks the diffusion of reactant, possibly atomic N, to the nitride/Si interface and thus prevent further nitridation. Nevertheless, the thickness of the RTP nitride fits the general requirement for the future ULSI technology. Moreover, the processing thermal budget at 1150° C. is certainly feasible. Thus the RTP N₂ may provide another attractive alternate for the future gate dielectrics.

Growth of Ultrathin Nitrogen-rich Oxynitride

Two different RTP process sequences were used to produce N-rich oxynitrides. In the first approach, Si surface is treated with N₂ gas at an elevated temperature (≧1150° C.) to form a thin Si₃N₄ film, as described above. The nitride films were then treated with O₂ in the RTP to produce N-rich oxynitride. The second method involves O₂ oxidation of the Si wafer to form SiO₂ first and then followed by exposure to N₂ to form nitrogen-rich oxynitride.

The growth of nitrogen rich oxynitrides is achieved by exposing SiO₂ films to N₂ at temperatures ≧1150° C. Three different SiO₂ films, with thicknesses of 50, 25 and 16 Å, were thermally grown under O₂ in the RTP at 1010, 910 and 850° C., respectively.

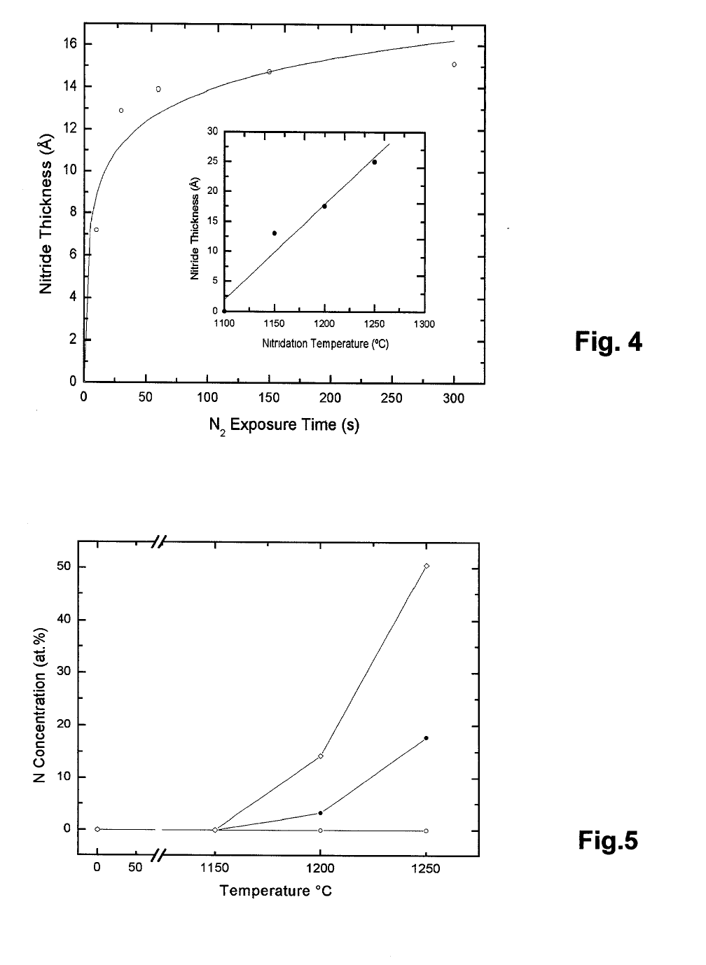

FIG. 4 shows the N content of these oxynitride films. It is observed that there is no nitrogen incorporation in the 50 Å SiO₂ film. Nitrogen incorporation, however, is found on thin (˜25 Å) films when the temperature is higher than 1150° C. The nitridation of the 16 A Si0₂ film shows a different behaviour as compared with the one obtained when nitriding the 25 Å SiO₂ film. The nitridation of the 16 A SiO₂ film at 1200° C. forms a nitrogen rich oxynitride film, while a Si₃N₄ is formed when nitrided at 1250° C. This indicate that the SiO₂ decomposes totally upon nitridation at 1250° C. and a new ultrathin pure nitride film is grown. The absence of nitrogen in the 50 Å SiO₂ film and the disappearance of oxygen in the 16 Å film indicate that nitridation occurs at the Si-dielectric interface. As soon as the temperature reaches a critical temperature (≧1150° C. in the cases investigated by the inventors to date), the SiO₂ film starts to decompose at the SiO₂/Si interface and nitride starts to form, provided that N can diffuse to the interface. XPS results indicate that the samples with an initial thickness of 50 Å SiO₂ were free of nitrogen. Conversely, the N 1 s spectrum for the samples with an initial SiO₂ thickness of 25 and 16 Å revealed the presence of nitrogen only when nitridation took place at 1200 and 1250° C. The films nitrided at 1150° C. reveal no presence of nitrogen. The N 1 s binding energies for the samples with an initial SiO₂ thickness of 25 Å that underwent nitridation at 1200 and 1250° C. for 60 s are 397.55 and 397.52 eV [11], respectively. These values are typical of binding energies obtained for oxynitride films. The N 1 s binding energies for the samples with an initial SiO₂ thickness of 16 Å that underwent nitridation at 1200 and 1250° C. for 60 s are 397.52 and 397.1 eV, respectively. The sample that was nitrided at 1250° C. shows a relatively low binding energy; it is comparable with that of a pure silicon nitride sample. The Si 2p spectrums for the nitrided samples with initial SiO₂ thicknesses of 16 Å were also obtained. The binding energies corresponding to the nitrided samples at 1150, 1200 and 1250° C., are 99.16, 99.12 and 99.12 for the Si⁰ peaks and 103.16, 102.92 and 101.5 for the Si⁺⁴ ones, respectively. The Si⁺⁴ peak location decreases with increasing nitridation temperature. The chemical shift for the nitrided sample at 1150° C. is 4 eV, which matches that of SiO₂ with a comparable thickness, thus confirming again the absence of nitrogen upon nitridation at 1150° C. The chemical shift for the nitrided sample at 1200° C. is 3.8 eV, while it is 2.38 eV for that nitrided at 1250° C. A chemical shift of 2.38 eV is typical of a pure Si₃N₄ film [9]. This observation confirms the conclusion obtained earlier with regards to the mechanism of nitridation, which takes place at the Si/SiO₂ interface. The sample nitrided at 1200° C. forms an oxynitride film denoted by a chemical shift that falls between that of a pure nitride and that of SiO₂.

Electrical Characteristics of Nitrogen-rich Oxynitride

FIG. 5 shows a high frequency capacitance-voltage of various dielectric films. The SiON sample grown by the nitridation of the 16 Å SiO₂ film at 1200° C., displays a rather “smeared out” C-V curve due to the presence of positive interface charges. The accumulation of interface trapped charges is most likely the result of nitridation. The derived electrical thickness (17 Å) is relatively higher than the physical thickness (14 Å) as measured by XPS. This is expected as due to the wave nature of electrons and it has been reported that the thickness extracted from the C-V data is approximately 3-5 A larger. The 32 Å SiON film, grown by oxidation of nitride, shows a flatband voltage of −0.35 V, which is lower than that of the reference SiO₂ (−0.75). The oxynitride shows a lower threshold voltage that makes it an attractive candidate for low power CMOS devices. The presence of nitrogen atoms in the dielectrics is proven to be an effective diffusion barrier against boron penetration in PMOS transistor.

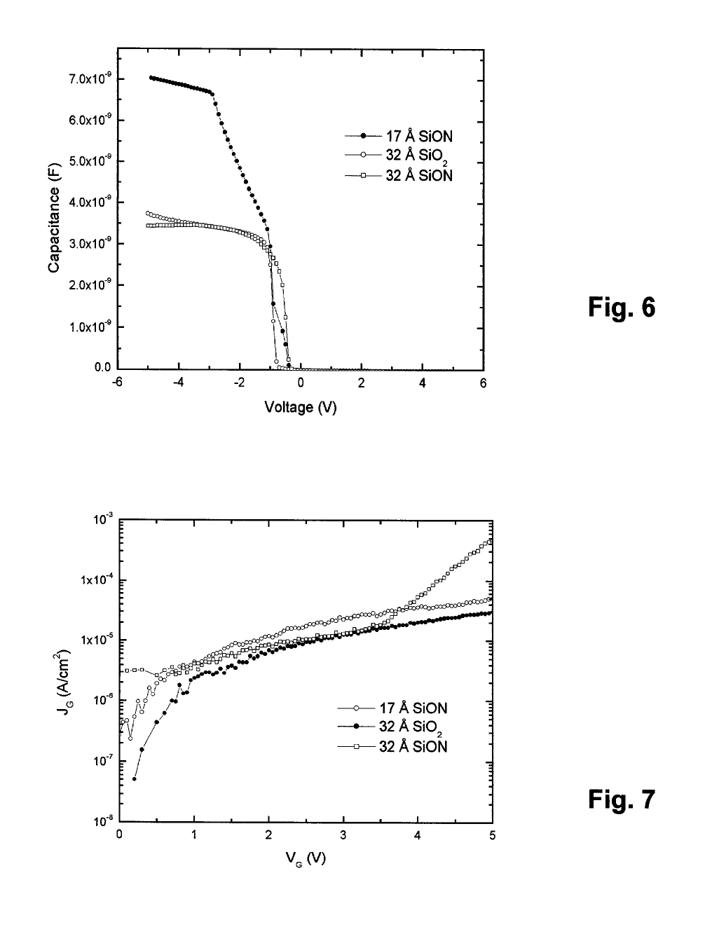

FIG. 6 shows a current-voltage characteristics of various dielectric films. The leakage current measured from both types of oxynitride films is comparable to that obtained from a 32 Å SiO₂. For the nitrogen rich ultra-thin oxynitride (17 Å), we find a tremendous improvement in leakage current thus making the film a potential candidate for sub 2 nm gate dielectrics. At 2 V, the nitrogen rich oxynitride developed by oxidation followed by nitridation exhibits a leakage current of 1.2×10⁻⁵ A/cm². This value is much lower than those reported for a 24 Å NO grown oxynitride by K. Kumar, A. I. Chou, C. Lin, P. Choudhury, J. C. Lee, and J. Lowell in Appl. Phys. Lett. 70, 384 (1997), a 19 Å N₂O oxynitride, and a Ta₂O₅ gate stack with EOT of 19 Å reported by Q. Lu, D. Park, A. Kalnitsky, C. Chang, C.C. Cheng, S. P. Tay, T. J. King, and C. Hu in IEEE Elect. Dev. Lett. 19, 341 (1998).

Obviously, many modifications and variations of the present invention are possible in light of the above teachings. It is therefore to be understood that, within the scope of the appended claims, the invention may be practiced otherwise than as specifically described. It is especially to be understood that the introduction of catalytic gases which lower the temperature of decomposition of an oxide film and allow excellent film electrical characteristics equivalent to those shown in the above specification are anticipated by the inventors.

We claim:

1. A method for Rapid Thermal Processing (RTP) for producing a film on a surface of a semiconductor wafer comprising silicon, comprising the steps;
a) introducing the wafer into the processing chamber of an RTP system; and
b) rapidly heating the semiconductor wafer to a temperature T greater than 1050° C. in an atmosphere of at least one nitrogen containing gas, wherein the atmosphere is sufficiently free of oxygen containing gases that oxygen is at least partially removed from a first thin film on the surface of the wafer, and wherein nitrogen from the nitrogen containing gas reacts with the surface and is incorporated into the first thin film on the surface of the semiconductor wafer.

2. The method of claim 1, wherein no oxygen remains in the first thin film on the surface of the semiconductor wafer after step b.

3. The method of claim 2, wherein the wafer is rapidly heated to a temperature greater than or equal to 1150° C. in step b.

4. The method of claim 3, further comprising the sequential step c of rapidly heating the wafer in an atmosphere containing a sufficient level of an oxygen containing gas that oxygen is incorporated in a second thin film on the surface of the semiconductor wafer.

5. The method of claim 3, wherein the wafer is rapidly heated to a temperature greater than or equal to 1200° C. in step b.

6. The method of claim 1, wherein the first thin film grows during the heating of the wafer to the temperature T.

7. The method of claim 1, wherein silicon, oxygen, and nitrogen remain in the first thin film on the surface of the semiconductor wafer after step b.

8. The method of claim 7, wherein the wafer is rapidly heated to a temperature greater than or equal to 1150° C. in step b.

9. The method of claim 7, further comprising the sequential step c of rapidly heating the wafer in an atmosphere containing a sufficient level of an oxygen containing gas that the first thin film is increased in thickness.

10. The method of claim 1, wherein the semiconductor wafer further comprises germanium.

11. The method of claim 1, wherein the nitrogen containing gas is N₂, NH₃, or NF₃.

12. The method of claim 11, further comprising the sequential step c of rapidly heating the wafer in an atmosphere containing a sufficient level of an oxygen containing gas that the thickness of the thin film is increased.

13. The method of claim 1, further comprising the sequential step c of rapidly heating the wafer in an atmosphere containing a sufficient level of an oxygen containing gas that the thickness of the first thin film is increased.

14. The method of claim 1, further comprising a step a′ between step a and step b, the step a′ comprising rapidly heating the wafer in an oxygen containing gas to produce the first thin film.

15. The method of claim 14, wherein step a′ and step b are performed in the same RTP chamber without removing the wafer from the chamber between steps a′ and b.
